(19) United States
(12) Patent Application Publication
(10) Pub. No.: US 2004/0014296 A1
(43) Pub. Date: Jan. 22, 2004

(54) Method for forming device isolation layer in semiconductor devices

(75) Inventors: Noh Yeal Kwak, Ichon-Shi (KR); Sang Wook Park, Seoul (KR)

Correspondence Address: MORGAN LEWIS & BOCKIUS LLP, 1111 PENNSYLVANIA AVENUE NW, WASHINGTON, DC, 20004, US

(73) Assignee: Hynix Semiconductor Inc.

(21) Appl. No.: 10/316,896

(22) Filed: Dec. 12, 2002

(30) Foreign Application Priority Data
Jul. 18, 2002 (KR) 2002-42158

(51) Int. Cl. H01L 21/76

(52) U.S. Cl. 438/424; 438/433; 438/435

(57) ABSTRACT

The present invention relates to a method of forming a device isolation film in a semiconductor device using a shallow trench. After the trench is formed, inert ion is implanted into a silicon substrate at upper and bottom edge portions of the trench, thus making amorphous the edge portions. The oxidization speed is increased as a reaction speed of silicon (Si) and oxygen (O₂) at the amorphous portions is increased. Thus, a peel-off phenomenon at the edge portions of the trench is prevented. As a result, as a phenomenon that a gate oxide film is thinly formed at the upper edge portion of the trench is prevented, generation of the leakage current due to centralized electric field and reliability of the device is improved accordingly.

### BACKGROUND OF THE INVENTION

1. Field of the Invention

The invention relates generally to a method of forming a device isolation film in a semiconductor device using a shallow trench, and more particularly to, a method of forming a device isolation film in a semiconductor device, capable of preventing a peel-off phenomenon occurring at the edge portion of a trench.

2. Description of the Prior Art

As the level of integration in the semiconductor memory devices is increased, the size of the memory cell is reduced. Therefore, in implementing the flash memory devices, a device isolation film using a shallow trench has recently been formed in order to secure the ratio of the memory cell per wafer.

Further, recently, in order to a wide channel length compared to the size of the cell, the device isolation film using the shallow trench is formed and a self-aligned floating gate is simultaneously formed.

Referring to FIG. 1A through FIG. 1C, a prior art method of forming a device isolation film in the semiconductor device will be described.

As shown in FIG. 1A, a pad oxide film 2 and a pad nitride film 3 are formed on a silicon substrate 1. The pad nitride film 3 and the pad oxide film 2 are then patterned so that the silicon substrate 1 in the device isolation region is exposed. Next, the silicon substrate 1 at the exposed portion is etched to form a shallow trench 4. Then, in order to compensate for damage due to etch, after the sidewall of the trench 4 is oxidized, a high-density plasma oxide film 5 is formed on the entire structure so that the trench 4 is buried. After the oxide film 5 and the pad nitride film 3 are planarized by a chemical mechanical polishing method, remaining pad nitride film 3 and pad oxide film 2 are removed to form the device isolation film 5 within the trench 4, as shown in FIG. 1B.

In the above conventional method, however, upon the oxidization process performed after the trench 4 is formed, a diffusion speed of oxygen (O₂) becomes slow at an upper edge portion ‘A’ of the trench 4, i.e., portion where the pad oxide film 2 and the silicon substrate 1 form an interface. In addition, as the bottom of the silicon crystal face at the bottom edge portion ‘B’ of the trench 4 is (100) faces, the side is (010) faces and edge is (111) faces, the oxidization speed in the horizontal direction and the oxidization speed in the longitudinal direction are varied. Therefore, as shown in FIG. 1C, a peel-off phenomenon is generated at the upper portion of the trench 4 and the bottom edge portions ‘C’ and ‘D’ of the trench. In a state that this peel-off phenomenon occurs, if a gate oxide film (not shown) is formed, the gate oxide film is formed thinly at the upper edge portion of the trench 4. Due to this, an electric field centralized phenomenon wherein the amount of the electric field is selectively increased at the edge portion when the electric field is applied, is generated. Resultantly, the leakage current is increased and an electrical characteristic of the device is thus degraded.

### SUMMARY OF THE INVENTION

The present invention is contrived to solve the above problems and an object of the present invention is to provide a method of forming a device isolation film in a semiconductor device wherein after a trench is formed, an upper portion and the bottom edge portion of the trench is made amorphous by implanting inert ion into the portions.

The above object of the present invention is achieved by a method of forming a device isolation film in a semiconductor device comprising the steps of forming a mask pattern on a silicon substrate and then etching the silicon substrate at an exposed portion by a, given depth to form a shallow trench, implanting inert ion into the silicon substrate of upper and bottom edge portions of the trench, oxidizing the sidewall of the trench in order to compensate for damage due to the etching, forming an oxide film on the entire structure so that the trench is buried, removing the oxide film and a portion of the mask pattern, and then performing planarization, and removing remaining mask pattern.

The inert ion is implanted at a tilt angle of 2 through 4° in depth of 40 through 60 Å.

The sidewall of the trench is formed in thickness of 50 through 200 Å using H₂O+N₂O gas wherein H₂O+N₂O is mixed at the ratio of 120 through 140 sccm: 80 through 100 sccm at a temperature of 800 through 900° C. and pressure of 1.8 through 4 Torr.

### BRIEF DESCRIPTION OF THE DRAWINGS

The aforementioned aspects and other features of the present invention will be explained in the following description, taken in conjunction with the accompanying drawings, wherein:

FIG. 1A through FIG. 1C are cross-sectional views of semiconductor devices for explaining a prior art method of forming a device isolation film in the semiconductor device; and

FIG. 2A through FIG. 2D are cross-sectional views of semiconductor devices for explaining a method of forming a device isolation film in the semiconductor device according to a preferred embodiment of the present invention.

### DETAILED DESCRIPTION OF PREFERRED EMBODIMENTS

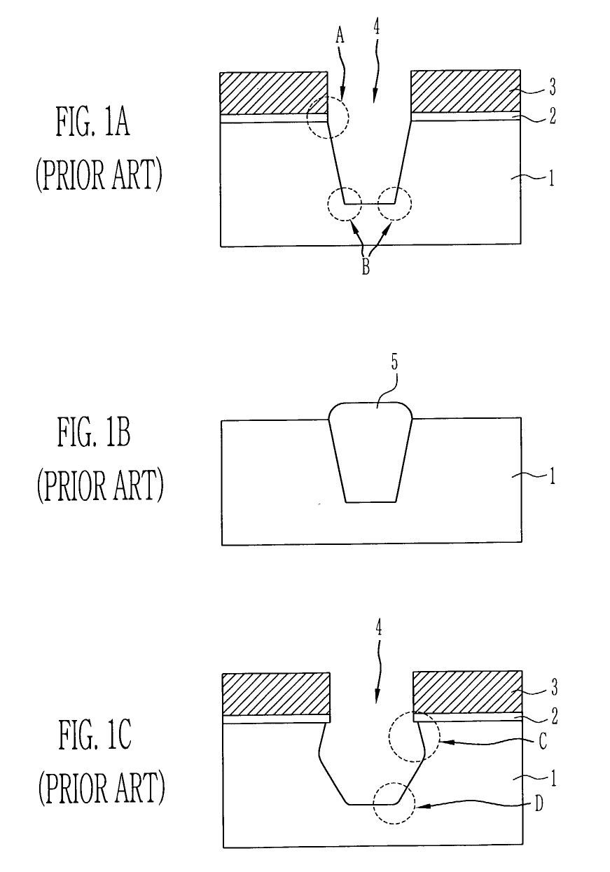

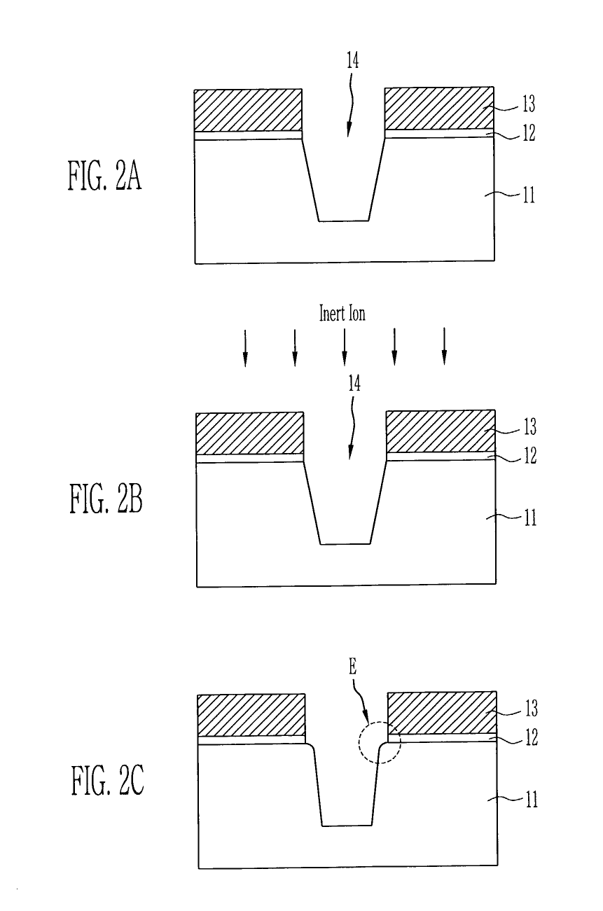

The peel-off phenomenon occurring the upper and bottom edge portions of the trench as shown in FIG. 1C is caused by difference in the low oxidization speed at the portion where the pad oxide film and silicon form the interface, and the longitudinal and horizontal oxidization speeds at the bottom edge portion of the trench. Therefore, the peel-off phenomenon can be prevented by increasing the oxidization speed at the upper and bottom edge portions of the trench.

The oxidization speed is greatly affected by solid-state diffusion between oxygen (O₂) and silicon (Si). Thus, in the present invention, after the trench is formed, the upper and bottom edge portions of the trench is made amorphous by implanting inert ion into the portions at the energy of an extent that the dangling bonding force between native atoms within the silicon substrate is lowered. As the activation energy between silicon atoms at the amorphous portion is low, the reaction speed of silicon (Si) and oxygen (O₂) due to reduced coupling force. Accordingly, the oxidization speed can be increased.

The present invention will be below described in detail by way of a preferred embodiment with reference to accompanying drawings.

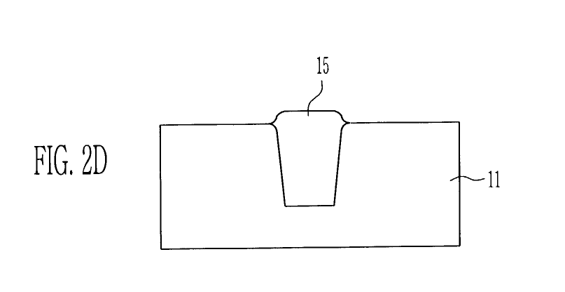

FIG. 2A through FIG. 2D are cross-sectional views of semiconductor devices for explaining a method of forming a device isolation film in the semiconductor device according to a preferred embodiment of the present invention.

Referring to FIG. 2A, a pad oxide film 12 and a pad nitride film 13 are sequentially formed on a silicon substrate 11. The pad oxide film 12 and the pad nitride film 13 are then patterned so that the silicon substrate 11 in the device isolation region is exposed. Next, the silicon substrate 11 at the exposed portion is etched to form a shallow trench 14.

In the above, the pad oxide film 12 is formed in thickness of 50 through 150 Å by a wet etch process under a H₂O+N₂O gas ambient wherein H₂O+N₂O is mixed at the ratio of 130 through 200 sccm: 70 through 90 sccm at a temperature of 800 through 900° C. and pressure of 1 through 2.5 Torr. At this time, if the wet etch process is used, it is possible to reduce the density of point defects that may occur at the interface with the silicon substrate 11 below 10² through 10³#/cm³.

Further, the pad nitride film 13 is formed in thickness of 1000 through 13000 Å by a low-pressure chemical vapor deposition (LPCVD) method under a SiH₄+N₂O gas ambient wherein SiH₄+N₂O is mixed at the ratio of 120 through 150 sccm:150 through 180 sccm at a temperature of 700 through 900° C. and pressure of 2.5 through 4 Torr. At this time, in the LPCVD method, the chemical composition ratio of SiH₄+N₂O is controlled using Si₃N₄ so that the pressure stress occurred at the interface with the pad oxide film 12 is below 102 through 10³dyne/cm. It is thus possible to prevent lifting.

Also, the trench 14 is formed in depth of 1000 through 5000 Å, wherein the corresponding angle of the bottom and side relating to a geometric structure is 80 through 85°.

FIG. 2B is a cross-sectional view of the semiconductor device wherein inert ion is implanted into the silicon substrate 11 of the upper and bottom edge portions of the trench 14. In the drawing, the silicon substrate 11 at the portion where inert ion is implanted is made amorphous.

Argon (Ar) is used as the inert ion. Ar is implanted in depth (Rp) of 40 through 60 Å at energy of an extent that the dangling bond force between native atoms can be lowered. At this time, Ar is implanted into the silicon substrate 11 of the upper and bottom edge portions of the trench 14 by controlling the ion implantation angle to be 2 through 4°.

Referring to FIG. 2C, the sidewall of the trench 14 is oxidized by a wet or a dry oxidization process in order to compensate for damage due to etching. As the surface of the trench 14 is made amorphous by implantation of ions, the activation energy of silicon (Si) is lowered and the coupling force is thus reduced. Due to this, the reaction speed of silicon (Si) and oxygen (O₂) is increased and the oxidization speed is thus increased. As a result, a peel-off phenomenon at the edge portion ‘E’ of the trench 14 can be prevented.

The wet oxidization process is performed at a temperature of 800 through 900° C. and pressure of 1.8 through 4 Torr under a H₂O+N₂O gas ambient wherein H₂O+N₂O is mixed at the ratio of 120 through 140 sccm: 80 through 100 sccm, so that an oxide film is grown in thickness of 50 through 200 Å.

Further, the dry oxidization process is performed at a temperature of 950 through 1050° C. and pressure of 1.2 through 2.2 Torr under a N₂O+O₂ gas ambient wherein N₂O+O₂ is mixed at the ratio of 110 through 140 sccm: 180 through 230 sccm, so that an oxide film is grown in thickness of 50 through 200 Å.

Referring to FIG. 2D, after the oxide film 15 is formed on the entire structure so that the trench 14 is buried, the oxide film 15 and the pad nitride film 13 are planarized by means of a chemical mechanical polishing (CMP) method. Next, remaining pad nitride film 13 and pad oxide film 12 are then removed to form a device isolation film 15 within the trench 14.

In the above, the oxide film 15 is formed by the dry or wet etch process so that the adhesive force with the silicon substrate 11 is doubled. At this time, the oxide film 15 is formed using a high-density plasma (HDP) oxide film having a high dielectric constant.

In the present invention, argon (Ar) is used as the inert dopant. As argon (Ar) is inset against silicon (Si), other compounds are not created. Argon (Ar) trapped at the silicon (Si) lattice is removed upon an annealing process for increasing the density of the oxide film buried within the trench (the annealing process is performed at a temperature of 900 through 1000° C. and pressure of 1.5 through 3 Torr under a N₂+Ar gas ambient wherein N₂+Ar is mixed at the ratio of 100 through 140 sccm:100 through 120 sccm) without performing additional annealing process. Thus, the concentration of argon (Ar) within the silicon substrate 11 can be kept below 5 through 7 ×10⁴#/cm³.

Further, additional mask process is not required since the pad oxide film 12 and the pad nitride film 13 used for forming the trench 14 are used as a mask when the inert ion is implanted.

As mentioned above, according to the present invention, after a trench is formed, a silicon substrate of upper and bottom edge portions of the trench is made amorphous by implanting inert ion at the energy of an extent that the dangling bond force between native atoms within the silicon substrate is lowered. Thus, as the activation energy between silicon atoms at the amorphous portion is low, the coupling force is reduced and the reaction speed of silicon (Si) and oxygen (O₂) is thus increased. As a result, the oxidization speed is increased.

Therefore, the present invention has advantageous effects that it can prevent a peel-off phenomenon at edge portions of the trench, a phenomenon that a gate oxide film oxide film is thinly formed, and a phenomenon that generation of the leakage current due to centralized electric field. Further, the present invention has advantageous effects that it can prevent line defects such as dislocation, twin, etc. that occur upper and bottom edges of the trench by the peel-off phenomenon, and improve GOI and breakdown characteristic at the device isolation film.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed is:

1. A method of forming a device isolation film in a semiconductor device, comprising the steps of:
forming a mask pattern on a silicon substrate and then etching the silicon substrate at an exposed portion by a given depth to form a shallow trench;
implanting inert ion into the silicon substrate of upper and bottom edge portions of the trench;
oxidizing the sidewall of the trench in order to compensate for damage due to the etching;
forming an oxide film on the entire structure so that the trench is buried, removing the oxide film and a portion of the mask pattern, and then performing planarization; and
removing remaining mask pattern.

2. The method as claimed in claim 1, wherein the mask pattern consists of a pad oxide film and a pad nitride film.

3. The method as claimed in claim 2, wherein the pad oxide film is formed in thickness of 50 through 150 Å using H₂O+N₂O gas wherein H₂O +N₂O is mixed at the ratio of 130 through 200 sccm:70 through 90 sccm at a temperature of 800 through 900° C. and pressure of 1 through 2.5 Torr.

4. The method as claimed in claim 2, wherein the pad nitride film is formed in thickness of 1000 through 13000 Å using SiH₄+N₂O gas wherein SiH₄+N₂O is mixed at the ratio of 120 through 150 sccm:150 through 180 sccm at a temperature of 700 through 900° C. and pressure of 2.5 through 4 Torr.

5. The method as claimed in claim 1, wherein the trench is formed in depth of 1000 through 5000 Å, wherein a corresponding angle between the bottom and the sidewall is 80 through 85°.

6. The method as claimed in claim 1, wherein the inert ion is argon (Ar).

7. The method as claimed in claim 1, wherein the inert ion is implanted at a tilt angle of 2 through 4° in depth of 40 through 60 Å.

8. The method as claimed in claim 1, wherein the sidewall of the trench is formed in thickness of 50 through 200 Å using H₂O+N₂O gas wherein H₂O+N₂O is mixed at the ratio of 120 through 140 sccm:80 through 100 sccm at a temperature of 800 through 900° C. and pressure of 1.8 through 4 Torr.

9. The method as claimed in claim 1, wherein the sidewall of the trench is formed in thickness of 50 through 200 Å using N₂O+O₂ gas wherein N₂O +O₂ is mixed at the ratio of 110 through 140 sccm: 180 through 230 sccm at a temperature of 950 through 1050° C. and pressure of 1.2 through 2.2 Torr.

10. The method as claimed in claim 1, wherein the oxide film is a high-density plasma oxide film.

11. The method as claimed in claim 1, wherein the planarization is performed using a chemical mechanical polishing method.
